(19) United States
(12) Patent Application Publication
(10) Pub. No.: US 2024/0170283 A1
(43) Pub. Date: May 23, 2024

(54) SELECTIVE DEPOSITION OF SILICON DIELECTRIC FILM

(71) Applicant: VERSUM MATERIALS US, LLC, TEMPE, AZ (US)

(72) Inventors: HARIPIN CHANDRA, SAN MARCOS, CA (US); RONALD M. PEARLSTEIN, SAN MARCOS, CA (US); XINJIAN LEI, VISTA, CA (US)

(21) Appl. No.: 18/548,846

(22) PCT Filed: Mar. 1, 2022
(86) PCT No.: PCT/US2022/018341

§ 371 Date: Sep. 1, 2023

Related U.S. Application Data
(60) Provisional application No. 63/155,669, filed on Mar. 2, 2021.

(51) Int. Cl. H01L 21/02; C23C 16/02; C23C 16/34; C23C 16/40; C23C 16/455; C23C 16/56

(52) U.S. Cl. CPC H01L 21/02326; C23C 16/0227; C23C 16/345; C23C 16/401; C23C 16/45536; C23C 16/45557; C23C 16/56; H01L 21/0214; H01L 21/02211; H01L 21/02216; H01L 21/02222; H01L 21/0228

(57) ABSTRACT

A method for selective deposition of a silicon and oxygen containing dielectric film onto a substrate is disclosed. The method includes the steps of providing a substrate comprising a dielectric surface and a metal, or metal hydride, surface to a reactor. A halogenated silicon-containing compound may be introduced to the reactor to form a silicon-containing layer more abundantly on the dielectric surface than on the metal, or metal hydride, surface. A nitrogen source may be introduced into the reactor to react with the silicon-containing layer to form a silicon nitride film or a carbon doped silicon nitride film. An oxygen-containing source may be introduced to the reactor to react with the silicon nitride or carbon doped silicon nitride film to form the silicon and oxygen containing dielectric film.

### CROSS-REFERENCE TO RELATED APPLICATIONS

This application is the National Stage entry of PCT/US2022/018341, filed on Mar. 1, 2022, which claims priority to U.S. Provisional Application Ser. No. 63/155,669, filed Mar. 2, 2021, the entire disclosures of which are hereby incorporated by reference herein.

### FIELD

Described herein is a composition and method for the fabrication of an electronic device. More specifically, described herein are compounds, and compositions and methods comprising same, for selectively depositing silicon oxide, silicon oxynitride, carbon doped silicon oxide, or carbon doped silicon oxynitride on dielectric materials in contrast with deposition on metal or metal hydride materials, to avoid/minimize oxidation of metal or metal hydride layer.

### BACKGROUND

U.S. Pat. No. 9,816,180 B discloses methods for selectively depositing onto a surface of a substrate relative to a second, different surface on which no deposition occurs. An exemplary deposition method includes selectively depositing a material, such as a material comprising nickel, nickel nitride, cobalt, iron, and/or titanium oxide on a first substrate surface, such as a silicon oxide surface, relative to a second, different surface, such as a H-terminated surface, of the same substrate. Methods include treating a surface of the substrate to provide H-terminations prior to deposition.

US publication 20180342388 A discloses methods of selectively depositing organic and hybrid organic/inorganic layers. More particularly, embodiments of the disclosure are directed to methods of modifying hydroxyl terminated surfaces for selective deposition of molecular layer organic and hybrid organic/inorganic films. Additional embodiments of the disclosure relate to cyclic compounds for use in molecular layer deposition processes.

US publication 20170037513 A discloses methods for selectively depositing a material on a first metal or metallic surface of a substrate relative to a second, dielectric. surface of the substrate, or for selectively depositing metal oxides on a first metal oxide surface of a substrate relative to a second silicon oxide surface. The selectively deposited material can be, for example, a metal, metal oxide, metal nitride, metal silicide, metal carbide and/or di electric material. In some embodiments a substrate comprising a first metal or metallic surface and a second dielectric surface is alternately and sequentially contacted with a first vapor-phase metal halide reactant and a second reactant. In some embodiments a substrate comprising a first metal oxide surface and a second silicon oxide surface is alternately and sequentially contacted with a first vapor phase metal fluoride or chloride reactant and water.

U.S. Pat. No. 10,460,930 B discloses methods and apparatuses for selectively depositing silicon oxide on a dielectric surface relative to a metal-containing surface such as copper. Methods involve exposing a substrate having dielectric and copper surfaces to a copper-blocking reagent such as an alkyl thiol to selectively adsorb to the copper surface, exposing the substrate to a silicon-containing precursor for depositing silicon oxide, exposing the substrate to a weak oxidant gas and igniting a plasma to convert the adsorbed silicon-containing precursor to form silicon oxide, and exposing the substrate to a reducing agent to reduce exposure of any oxidized copper to the weak oxidant gas.

US publication 20180211833 A discloses processing platforms having a central transfer station with a robot and an environment having greater than or equal to about 0.1% by wt. water vapor, a pre-clean chamber connected to a side of the transfer station and a batch processing chamber connected to a side of the transfer station. The processing platform is configured to pre-clean a substrate to remove native oxides from a first surface, form a blocking layer using an alkylsilane and selectively deposit a film. Methods of using the processing platforms and processing a plurality of wafers are also described.

US publication 20190023001 A discloses methods of selectively depositing a film on a hydroxide terminated surface relative to a hydrogen terminated surface. The hydrogen terminated surface is exposed to a nitriding agent to form an amine terminated surface which is exposed to a blocking molecule to form a blocking layer on the surface. A film can then be selectively deposited on the hydroxide terminated surface.

US publication 20180233349 A discloses methods and apparatuses for selectively depositing silicon oxide on a silicon oxide surface relative to a silicon nitride surface. Methods involve pre-treating a substrate surface using ammonia and/or nitrogen plasma and selectively depositing silicon oxide on a silicon oxide surface using alternating pulses of an aminosilane silicon precursor and an oxidizing agent in a thermal atomic layer deposition reaction without depositing silicon oxide on an exposed silicon nitride surface.

U.S. Pat. No. 10,043,656 B discloses methods and apparatuses for selectively depositing silicon-containing dielectric or metal containing dielectric material on silicon or metal surfaces selective to silicon oxide or silicon nitride materials. Methods involve exposing the substrate to an acyl chloride which is reactive with the silicon oxide or silicon nitride material where deposition is not desired to form a ketone structure that blocks deposition on the silicon oxide or silicon nitride material. Exposure to the acyl chloride is performed prior to deposition of the desired silicon-containing dielectric material or metal-containing dielectric material.

US publication 20180323055 A discloses a method for selectively forming a silicon nitride film on a substrate comprising a first metallic surface and a second dielectric surface by a cyclical deposition process. The method may comprise contacting the substrate with a first reactant comprising a silicon halide source and contacting the substrate with a second reactant comprising a nitrogen source, wherein the incubation period for the first metallic surface is less than the incubation period for the second dielectric surface. Semiconductor device structures comprising a selective silicon nitride film are also disclosed.

There is a need in the art to provide a composition and method of deposition of silicon dielectrics such as silicon oxide, silicon oxynitride, carbon doped silicon oxide, carbon doped silicon oxynitride selectively on top of a dielectric surface while avoiding deposition of such silicon dielectric material on an adjacent or present metal hydride surface in during semiconductor processing employing a thermal atomic layer deposition process. There is a further need in the art to provide such a selective deposition without employing strong oxidants such as ozone or an oxygen containing plasma.

### BRIEF SUMMARY

The present disclosure, according to one embodiment, includes a method for selective deposition of silicon and oxygen containing dielectric film onto a substrate, including:
a) providing at least one substrate comprising at least one dielectric surface and at least one metal or metal hydride surface, in a reactor,
b) heating the reactor to at least one temperature ranging from about 25° C. to about 600° C. and optionally maintaining the reactor at a pressure of about 100 torr or less;
c) introducing into the reactor at least one precursor comprising a halogenated silicon-containing compound that forms a silicon-containing layer more abundantly on the dielectric surface than on the metal or metal hydride surface;
d) purging away any unreacted precursor from the reactor using inert gas;
e) introducing a nitrogen source to react with the silicon-containing layer to form a silicon nitride film or a carbon doped silicon nitride film;
f) purging the reactor using inert gas;
g) introducing an oxygen-containing source into the reactor to react with the silicon nitride film or the carbon doped silicon nitride film to form the silicon and oxygen containing dielectric film;
h) purging away any unreacted oxygen-containing source from the reactor using inert gas; and
i) optionally treating the substrate to form a clean metal or metal hydride layer and a clean dielectrics layer using reducing agent; and repeating some or all of steps c through h or j until the silicon and oxygen containing dielectric film reaches a desired thickness.

### DETAILED DESCRIPTION

Described herein a method for thermally selective deposition of silicon and oxygen containing dielectric film onto a silicon-containing or metal-containing dielectrics surface without depositing onto an adjacent or otherwise present metal or metal hydride surface in an atomic layer deposition (ALD) or in an ALD-like process such as, without limitation, a cyclic chemical vapor deposition process (CCVD).

Conventional deposition systems use an oxidizer to form an oxygen containing dielectric film such as silicon oxide, silicon oxynitride, carbon doped silicon oxide, or carbon doped silicon oxynitride which is not preferred for deposition onto a metal surface. An oxidizer such as ozone and/or oxygen plasma can oxidize a metal/metal hydride surface to form a metal oxide surface, thereby prohibiting selective deposition of a dielectric film onto the dielectric vs metal/metal hydride surfaces. The present disclosure is directed to a thermal deposition of silicon and oxygen containing dielectrics films process. The process steps include thermal deposition of a silicon nitride or carbon doped silicon and then converting into silicon oxide, silicon oxynitride, carbon doped silicon oxide, or carbon doped silicon oxynitride, thus avoiding or minimizing oxidation of a metal or metal hydride layer during depositions. Any relatively minimal oxidation layer that forms on the metal/metal hydride can be removed via reduction using a reducing agent such as hydrogen, hydrogen-containing plasma or forming gas (mixture of hydrogen and nitrogen) or silane or polysilanes or alcohols or other reduction means after forming a desired silicon oxide, silicon oxynitride, carbon doped silicon oxide, and/or carbon doped silicon oxynitride on the dielectric layer.

The method described according to an exemplary embodiment comprises:
a) providing at least one substrate comprising at least one first surface and at least one second surface in a reactor, wherein the at least one first surface is a dielectric surface and the at least one second surface is a silicon surface, a metal surface, a metal compound surface, or hydride surfaces thereof;
b) heating the reactor to at least one temperature ranging from about 25° C. to about 600° C. and optionally maintaining the reactor at a pressure of about 100 torr or less;
c) introducing into the reactor at least one precursor comprising a halogenated silicon-containing compound that forms a silicon-containing layer more abundantly on the at least one first surface than on the at least one second surface;
d) purging any unreacted precursor from the reactor using inert gas;
e) introducing a nitrogen source to react with the silicon-containing layer to form a silicon nitride film or a carbon doped silicon nitride film;
f) purging the reactor using inert gas;
g) introducing an oxygen-containing source into the reactor to react with the silicon nitride film or the carbon doped silicon nitride film to form a silicon and oxygen containing dielectric film;
h) purging any unreacted oxygen-containing source from the reactor using inert gas;
i) optionally treating the substrate to form a clean metal hydride layer and a clean dielectrics layer using a reducing agent.

Steps c to fin this embodiment may be repeated to provide a desired thickness of silicon nitride or carbon doped silicon nitride before steps g to i are introduced to form a stable form silicon and oxygen containing dielectric film. In some particular embodiments of this disclosure, steps c to f are repeated to achieve a desired thickness of silicon nitride or silicon carbonitride before introducing the oxygen-containing source in step g. The thickness of silicon nitride or silicon carbonitride ranges from 1 Å to 1000 Å, or 1 Å to 500 Å, or 1 Å to 300 Å, or 1 Å to 200 Å, or 1 Å to 100 Å, or 1 Å to 50 Å. The thickness of the of silicon nitride or silicon carbonitride range may also range from 5 Å to 500 Å, or 5 Å to 400 Å, or 5 Å to 300 Å, or 5 Å to 200 Å, or 5 Å to 100 Å, or 5 Å to 50 Å.

Steps c through h, or c to i, may be repeated until a desired thickness of silicon oxide form silicon and oxygen containing dielectric film is selectively deposit on the first surface, i.e., dielectric surface in this particular embodiment of the method disclosed herein.

In an additional embodiment, a deposition process may include the steps of:
a) providing at least one substrate comprising at least one first surface and at least one second surface, in a reactor, wherein the at least one first surface is a dielectric surface and the at least one second surface is a silicon surface, a metal surface, a metal compound surface, or hydride surfaces thereof;
b) heating the reactor to at least one temperature ranging from about 25° C. to about 600° C. and optionally maintaining the reactor at a pressure of about 100 torr or less;
c) introducing into the reactor at least one precursor comprising a halogenated silicon-containing compound that forms a silicon-containing layer more abundantly on the at least one surface than on the at least one second surface;
d) purging any unreacted precursor from the reactor using inert gas;
e) introducing a nitrogen source to react with the silicon-containing layer to form silicon nitride or a carbon doped silicon nitride film;
f) purging the reactor using inert gas
g) optionally treating the substrate to form a clean metal hydride layer and a clean dielectrics layer using a reducing agent;
h) introducing an oxygen-containing source into the reactor to react with the silicon nitride or carbon doped silicon nitride film to form a silicon and oxygen containing dielectric film;
i) purging any unreacted oxygen-containing source from the reactor using inert gas;
   Steps c to fin this particular embodiment may be repeated to provide a desired thickness of silicon nitride or carbon doped silicon nitride before steps g to h, or steps g to i, are introduced to form a stable form silicon and oxygen containing dielectric film. In some embodiments of this disclosure, steps c to f are repeated to achieve a desired thickness of silicon nitride or silicon carbonitride before step g or h is introduced. The thickness of silicon nitride or silicon carbonitride ranges from 1 Å to 1000 Å, or 1 Å to 500 Å, or 1 Å to 300 Å, or 1 Å to 200 Å, or 1 Å to 100 Å, or 1 Å to 50 Å. The thickness of the of silicon nitride or silicon carbonitride range may also range from 5 Å to 500 Å, or 5 Å to 400 Å, or 5 Å to 300 Å, or 5 Å to 200 Å, or 5 Å to 100 Å, or 5 Å to 50 Å.

Steps c through i may be repeated until a desired thickness of silicon oxide form silicon and oxygen containing dielectric film is selectively deposit on the dielectric surface in this embodiment of the method disclosed herein.

Examples of the nitrogen source can be selected from ammonia, ethylenediamine, methylenediamine and piperazine.

The oxygen-containing source is preferred using a mild oxidant which can be selected from air, molecular oxygen, nitrous oxide, water vapor or hydrogen peroxide.

The oxygen-containing source can also be selected from ozone, oxygen plasma, nitrous oxide plasma, carbon dioxide plasma and combinations thereof.

The at least one second surface can be selected from Si, Co, Cu, Al, Ta, Mo, W, TiN, TiSi, MoN, WN, and hydrides thereof. The dielectric surface can be selected from a metal oxide layer such as Cu oxide, Ta oxide, Al oxide, silicon oxide, carbon doped silicon oxide, Mo oxide, Ti oxide; Al nitride, silicon nitride; or combinations thereof which may include carbon doped silicon oxynitride or silicon oxynitride.

The reducing agent may be selected from hydrogen, and hydrogen containing plasma.

Exemplary halogenated silicon-containing compounds to selectively deposit silicon oxide or silicon oxynitride are selected from the group consisting of:
i) halogenated silanes, ii) halogenated siloxanes, iii) halogenated silazanes, and iv) halogenated carbosilanes.

The halogenated silanes of group i include but are not limited to, trichlorosilane, tetrachlorosilane, hexachlorodisilane, pentachlorodisilane, tetrachlorodisilane, octachlorotrisilane, dichlorosilane.

The halogenated siloxanes of group ii include, but are not limited to, hexachlorodisiloxane, pentachlorodisiloxane, tetrachlorodisiloxane, octaclorotrisiloxane.

The halogenated silazanes of group iii are selected from the groups represented by the following Formula I below:

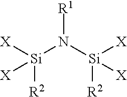

wherein R¹ is selected from the group consisting of hydrogen, a linear or branched C₁ to C₁₀ alkyl group, a linear or branched C₃ to C₁₀ alkenyl group, a linear or branched C₃ to C₁₀ alkynyl group, a C₃ to C₁₀ cyclic alkyl group, a C₂ to C₆ dialkylamino group, an electron withdrawing group, and a C₆ to C₁₀ aryl group; R² is selected from the group consisting of hydrogen, a linear or branched C₁ to C₁₀ alkyl group, a linear or branched C₂ to C₆ alkenyl group, a linear or branched C₃ to C₆ alkynyl group, a C₃ to C₁₀ cyclic alkyl group, a C₂ to C₆ dialkylamino group, a C₆ to C₁₀ aryl group, a linear or branched C₁ to C₆ fluorinated alkyl group, an electron withdrawing group, a C₄ to C₁₀ aryl group, and a halide selected from the group consisting of Cl, Br, and I; and X is a halide selected from the group consisting of Cl, Br, and I.

Examples of group iii of halogenated silazanes may be represented in structures below.

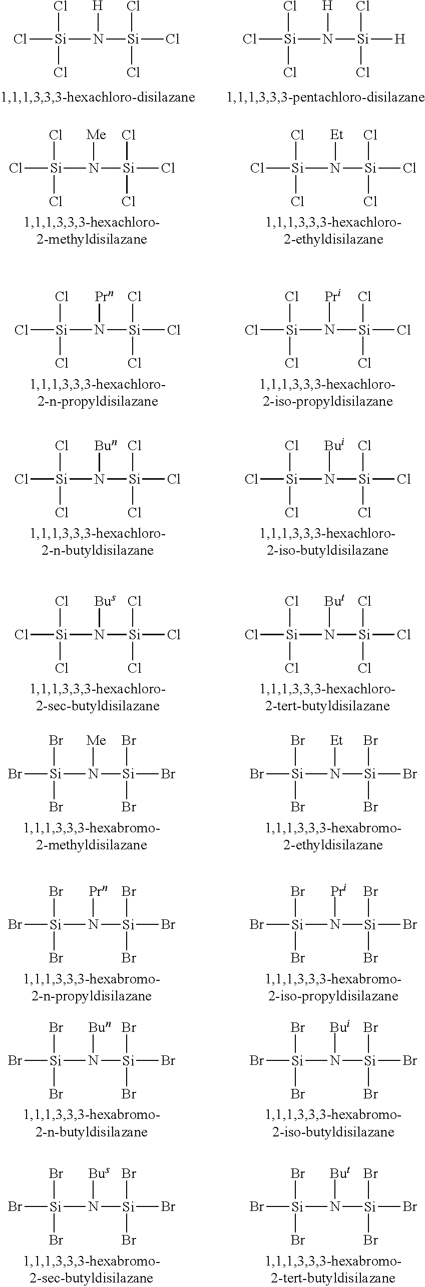

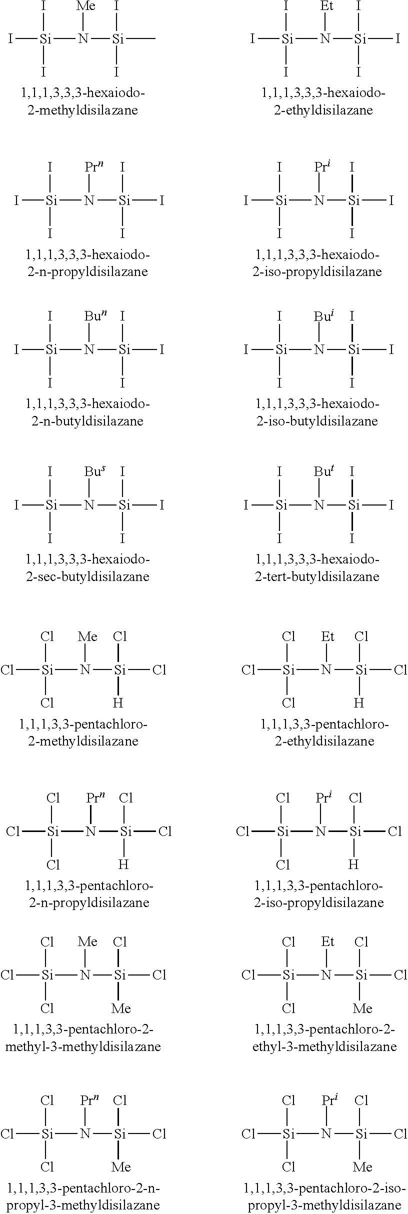

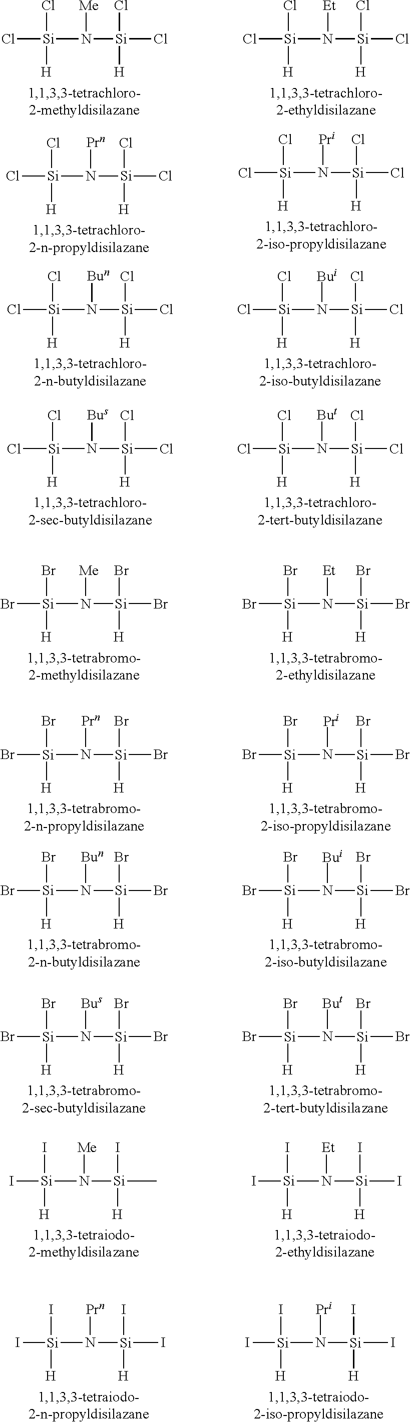

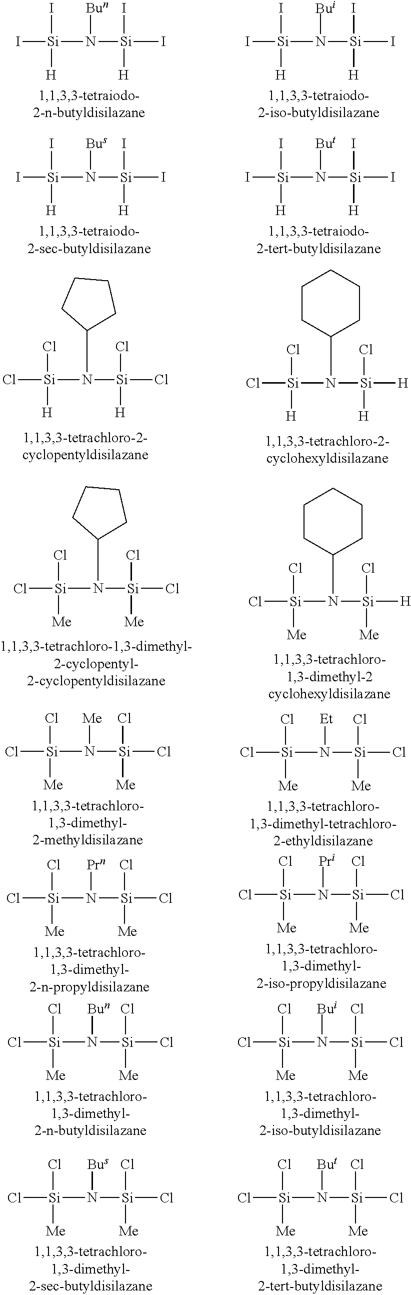

The halogenated carbosilanes of group iv A are selected from the group consisting of silicon compounds having one or two Si—C—Si linkages. Exemplary carbosilanes of group iv include those represented by Formulae II, and III:

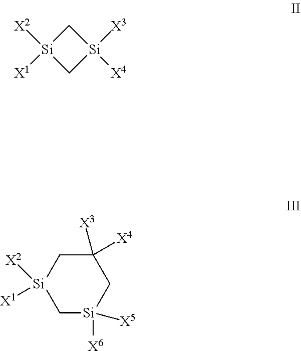

wherein X¹, X², X³, X⁴, X⁵, and X⁶ are each independently chosen from a H atom; a halide atom selected from F, Cl, Br, and I; isocyanate; an amino group having the formula NR¹R² wherein R¹ and R² are independently selected from the group consisting of hydrogen, a C₁₋₁₀ linear alkyl group; a C₃₋₁₀ branched alkyl group; a C₃₋₁₀ cyclic alkyl group; a C₃₋₁₀ alkenyl group; a C₄₋₁₀ aryl group; and a C₄₋₁₀ heterocyclic group; In some embodiments of Formula II, III or both II and III, and one or more of substituents X¹, X², X³, X⁴, X⁵, and X⁶ is linked to form a substituted or unsubstituted, saturated or unsaturated, cyclic group. In one embodiment of Formula II, III, or both II and III, any one or more of substituents X¹, X², X³, X⁴, X⁵, and X⁶ is either halide or amino group described above. For Formulae II and III, X¹, X², X³, X⁴, X⁵, and X⁶ cannot be all amino groups. In certain embodiments of Formula II or III, R¹ and R² in the amino group having the formula NR¹R² are linked together to form a ring. In one particular embodiment, R¹ and R² are selected from a linear or a branched C₃ to C₆ alkyl group and are linked to form a cyclic ring. In alternative embodiments of Formula II or III, R¹ and R² are not linked together to form a ring. In other embodiments, R¹ and R² are different.

Examples of group iv halogenated carbosilanes may be represented by the structures below:

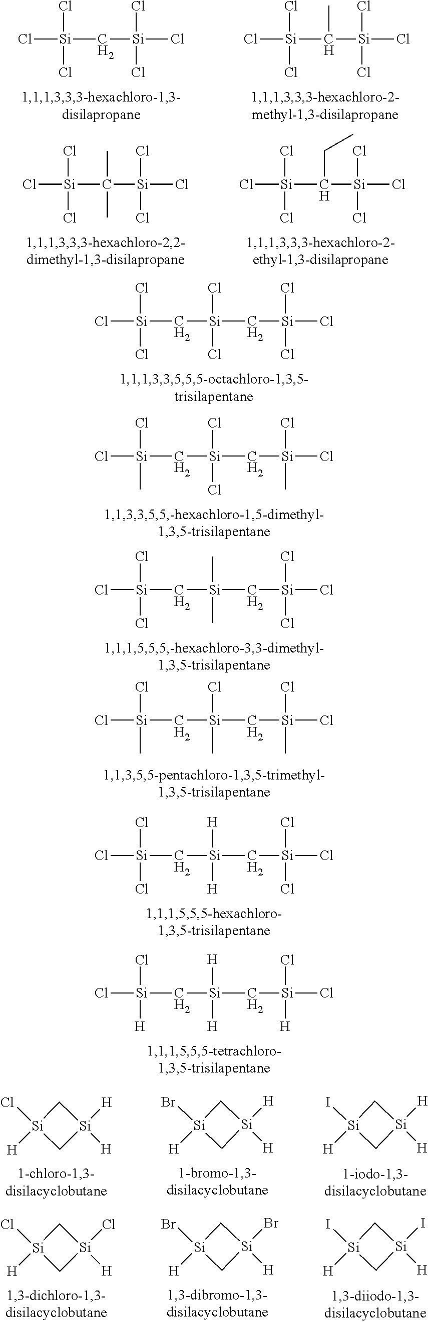

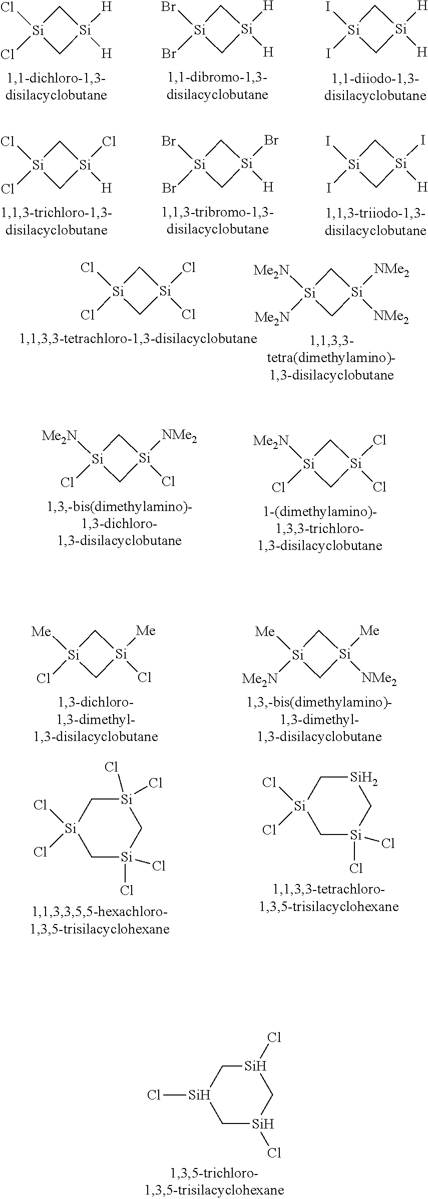

### EXAMPLE 1

### Deposition of Carbon Doped Silicon Oxide Films on Silicon Dielectrics (Silicon Oxide or Silicon Nitride) but not on Silicon Hydride Using 1,1,3,3-tetrachloro-1,3-disilacyclobutane

Selective deposition of silicon dielectric films was performed on different type of surfaces such as silicon dielectrics and silicon hydride. Silicon dielectrics surface was selected from commercially available films such as thermally grown silicon oxide (1000 Å), LPCVD grown silicon nitride (1000 Å) on silicon wafer while silicon hydride surface was prepared by removing native oxide from the silicon wafers. Three coupons of each type were used.

Prior to deposition, all coupons were cleaned by standard semiconductor cleaning (SC-1) process for 10 minutes at 70° C. The SC-1 solution consisted of 30% H₂O₂:27% NH₄OH:DI water ratio of 1:1:5. After SC-1 cleaning and rinse with DI water, all coupons was subjected to 0.5% HF solution at room temperature for 90 seconds for further removal of contaminants and native silicon oxide on coupons surface. SCI Filmtek 3000, transmission-reflection spectrophotometer, was used to measure film thickness before and after depositions.

Selective growth of silicon-containing films on silicon dielectrics, not on silicon hydride, was demonstrated by deposition of thermal ALD process using 1,1,3,3-tetrachloro-1,3-disilacyclobutane and ammonia as reactant gas.

Deposition process was performed on a 300 mm PEALD tool with both inner and outer chambers. Film growth ALD steps are listed on Table 1 below:

TABLE 1

| | Descriptions | Time | | Notes |
|---|---|---|---|---|
| 1 | Insert Si substrates | | | |
| | into a reactor | | | |
| 2 | Heat substrates to | 15 | mins | T = 300° C. |
| | desired temperature | | | |
| 4. | Flow gases to | 5 | s | Inner chamber pressure = 8 Torr; |
| | stabilize flow | | | Outer chamber pressure = 7.5 Torr |
| | | | | Carrier Ar gas to outer chamber = |
| | | | | 500 sccm |
| | | | | Ar purge = 300 sccm |
| 3 | Flow 1,1,3,3- | 1 | s | Inner chamber pressure = 8 Torr; |
| | tetrachloro-1,3- | | | Outer chamber pressure = 7.5 Torr |
| | disilacyclobutane | | | Carrier Ar gas to outer chamber = |
| | Si precursor to | | | 500 sccm |
| | the reactor | | | Ar purge = 300 sccm |
| | | | | Flow Si precursor by vapor draw |
| 4 | Soak | 3 | s | Close throttle valve and stop all |
| | | | | gas flow |
| 5. | Purge Si precursor | 10 | s | Inner chamber pressure = 8 Torr; |
| | out | | | Outer chamber pressure = 7.5 Torr |
| | | | | Carrier Ar gas to outer chamber = |
| | | | | 500 sccm |
| | | | | Ar purge = 300 sccm |
| 5 | Flow NH₃ to the | 25 | s | Inner chamber pressure = 8 Torr; |
| | reactor | | | Outer chamber pressure = 7.5 Torr |
| | | | | Carrier Ar gas to outer chamber = |
| | | | | 500 sccm |
| | | | | Ar purge = 300 sccm |
| | | | | NH₃ = 200 sccm |
| 6 | Purge NH₃ out | 10 | s | Inner chamber pressure = 8 Torr; |
| | | | | Outer chamber pressure = 7.5 Torr |
| | | | | Carrier Ar gas to outer chamber = |
| | | | | 500 sccm |
| | | | | Ar purge = 300 sccm |
| 7 | Remove Si sample | | | |
| | from the reactor | | | |

Steps 3 to 6 were repeated multiple times to get the desired film thickness. The film was exposed to air at ambient temperature to convert the as-deposited carbon doped silicon nitride to carbon doped silicon oxide.

Table 2 shows thickness of carbon doped silicon oxide film growth on various surface. The reported data only shows thickness growth, initial film thickness subtracted from the final film thickness. Standard deviation (std. dev.) is one sigma, calculated from three measurements (one measurement on each coupon).

TABLE 2
Comparison of carbon doped silicon oxide film
growth on different surfaces.

| | Silicon hydride | | Silicon oxide | | Silicon nitride | |
|---|---|---|---|---|---|---|
| | surface | | surface | | surface | |
| | Film | Std. | Film | Std. | Film | Std. |
| # of | growth | dev. | growth | dev. | growth | dev. |
| cycle | (Å) | (Å) | (Å) | (Å) | (Å) | (Å) |
| 25 | 0.6 | 0.4 | 10.4 | 3.1 | 12.3 | 5.3 |
| 50 | 9.0 | 0.6 | 22.3 | 0.9 | 23.8 | 2.2 |
| 100 | 25.6 | 0.7 | 45.9 | 0.9 | 39.1 | 4.3 |

Film growth on silicon hydride was clearly impeded compared to other surfaces (silicon oxide and silicon nitride). Very low film growth observed on silicon hydride surface after 25 cycles (<1 Å) while film growth on silicon oxide and silicon nitride surfaces are 10 Å and 12 Å respectively.

What is claimed is:

1. A method for selective deposition of a silicon and oxygen containing dielectric film onto a substrate, comprising:
a) providing at least one substrate comprising at least one first surface and at least one second surface in a reactor, wherein the at least one first surface is a dielectric surface and the at least one second surface is a silicon surface, a metal surface, a metal compound surface, or hydride surfaces thereof;
b) heating the reactor to at least one temperature ranging from about 25° C. to about 600° C. and optionally maintaining the reactor at a pressure of about 100 torr or less;
c) introducing into the reactor at least one precursor comprising a halogenated silicon-containing compound that forms a silicon-containing layer more abundantly on the at least one surface than on the at least one second surface;
d) purging any unreacted precursor from the reactor using inert gas;
e) introducing a nitrogen source to react with the silicon-containing layer to form silicon nitride or a carbon doped silicon nitride film;
f) purging the reactor using inert gas;
g) introducing an oxygen-containing source into the reactor to react with the silicon nitride or the carbon doped silicon nitride film to form the silicon and oxygen containing dielectric film;
h) purging any unreacted oxygen-containing source from the reactor using inert gas; and
i) optionally treating the substrate to form a clean metal hydride layer and a clean dielectrics layer using a reducing agent.

2. The method of claim 1, wherein the at least one second surface comprises at least one selected from the group consisting of Si, Co, Cu, Al, Ta, Mo, W, TiN, TiSi, MoN, WN, and hydrides thereof.

3. The method of claim 1, wherein the at least one first surface is selected from the group consisting of Cu oxide, Ta oxide, Al oxide, silicon oxide, carbon doped silicon oxide, carbon doped Mo oxide, carbon doped Ti oxide, Al nitride, silicon nitride, carbon doped silicon oxynitride, and silicon oxynitride.

4. The method of claim 1, wherein the silicon and oxygen-containing dielectric film is selected from the group consisting of silicon oxide, carbon doped silicon oxide, silicon oxynitride, and carbon doped silicon oxynitride.

5. The method of claim 1, wherein the halogenated silicon-containing compound is selected from the consisting of i) halogenated silanes, ii) halogenated siloxanes, iii) halogenated silazanes, and iv) halogenated carbosilanes.

6. The method of claim 1, wherein nitrogen source is selected from the group consisting of ammonia, ethylenediamine, methylenediamine and piperazine.

7. The method of claim 1, wherein the oxygen-containing source is introduced after silicon nitride or carbon doped silicon nitride film is deposited to a predetermined thickness by repeating steps c to f.

8. The method of claim 1, wherein when repeating some or all of steps c through h, the oxygen-containing source is always introduced after the nitrogen source is introduced to react with the silicon-containing layer.

9. The method of claim 1, wherein the oxygen-containing source is selected from the group consisting of air, molecular oxygen, nitrous oxide, water vapor and hydrogen peroxide.

10. The method of claim 1, wherein the oxygen-containing source is selected from ozone, oxygen plasma, nitrous oxide plasma, carbon dioxide plasma and combinations thereof.

11. The method of claim 1 comprising step i, which comprises introducing hydrogen or hydrogen plasma as the reducing agent into the reactor to remove some residual films and clean the at least one second surface.

12. A method for selective deposition of a silicon and oxygen containing dielectric film onto a substrate, comprising:
a) providing at least one substrate comprising at least one first surface and at least one second surface in a reactor, wherein the at least one first surface is a dielectric surface and the at least one second surface is a silicon surface, a metal surface, a metal compound surface, or hydride surfaces thereof;
b) heating the reactor to at least one temperature ranging from about 25° C. to about 600° C. and optionally maintaining the reactor at a pressure of about 100 torr or less;
c) introducing into the reactor at least one precursor comprising a halogenated silicon-containing compound that forms a silicon-containing layer more abundantly on the at least one first surface than on the at least one second surface;
d) purging away any unreacted precursor from the reactor using inert gas;
e) introducing a nitrogen source to react with the silicon-containing layer to form a silicon nitride film or a carbon doped silicon nitride film;
f) purging the reactor using inert gas;
g) exposing the silicon nitride film or carbon doped silicon nitride film to an oxygen-containing source to react with the silicon nitride or the carbon doped silicon nitride film to form the silicon and oxygen containing dielectric film;
h) purging away any unreacted oxygen-containing source from the reactor using inert gas, only when the oxygen-containing source is introduced into the reactor; and
i) optionally treating the substrate to form a clean metal or metal hydride layer and a clean dielectrics layer using a reducing agent; and repeating some or all of steps c through h until the silicon and oxygen containing dielectric film reaches a desired thickness.

13. The method of claim 12, wherein the at least one second surface comprises at least one selected from the group consisting of Si, Co, Cu, Al, Ta, Mo, W, TiN, TiSi, MoN, WN, and hydrides thereof.

14. The method of claim 12, wherein the at least one first surface is selected from the group consisting of Cu oxide, Ta oxide, Al oxide, silicon oxide, carbon doped silicon oxide, carbon doped Mo oxide, carbon doped Ti oxide, Al nitride, silicon nitride, carbon doped silicon oxynitride, and silicon oxynitride.

15. The method of claim 12, wherein the silicon and oxygen-containing dielectric film is selected from the group consisting of silicon oxide, carbon doped silicon oxide, silicon oxynitride, and carbon doped silicon oxynitride.

16. The method of claim 12, wherein the halogenated silicon-containing compound is selected from the consisting of i) halogenated silanes, ii) halogenated siloxanes, iii) halogenated silazanes, and iv) halogenated carbosilanes.

17. The method of claim 12, wherein nitrogen source is selected from the group consisting of ammonia, ethylenediamine, methylenediamine and piperazine.

18. The method of claim 12, wherein the silicon nitride film or carbon doped silicon nitride film is exposed to the oxygen-containing source after the silicon nitride or carbon doped silicon nitride film is deposited to a predetermined thickness by repeating steps c to f.

19. The method of claim 12, wherein when repeating some or all of steps c through h, the silicon nitride film or carbon doped silicon nitride film is exposed to the oxygen-containing source only after the nitrogen source is introduced to react with the silicon-containing layer.

20. The method of claim 12, wherein the silicon nitride film or carbon doped silicon nitride film is exposed to the oxygen-containing source while in the reactor, and wherein the oxygen-containing source is selected from the group consisting of air, molecular oxygen, nitrous oxide, water vapor and hydrogen peroxide.

21. The method of claim 12, wherein the silicon nitride film or carbon doped silicon nitride film is exposed to the oxygen-containing source while in the reactor, and wherein the oxygen-containing source is selected from the group consisting of ozone, oxygen plasma, nitrous oxide plasma, carbon dioxide plasma and combinations thereof.

22. The method of claim 12, wherein the silicon nitride film or carbon doped silicon nitride film is exposed to the oxygen containing source while outside the reactor, and wherein the oxygen-containing source is air.

23. The method of claim 12 further comprising step i, which comprises introducing hydrogen or hydrogen plasma as the reducing agent into the reactor to remove some residual films and clean the at least one second surface.
